(19) United States
(12) Patent Application Publication
(10) Pub. No.: US 2020/0186133 A1
(43) Pub. Date: Jun. 11, 2020

(54) TIME-DELAY CIRCUIT

(71) Applicant: Commissariat à l'Énergie Atomique et aux Énergies Alternatives, Paris (FR)

(72) Inventors: Gérard Billiot, Grenoble Cedex 9 (FR); Franck Badets, Voiron (FR)

(73) Assignee: Commissariat à l'Énergie Atomique et aux Énergies Alternatives, Paris (FR)

(21) Appl. No.: 16/708,807

(22) Filed: Dec. 10, 2019

(30) Foreign Application Priority Data
Dec. 11, 2018 (FR) 1872691

(51) Int. Cl. H03K 5/01

(52) U.S. Cl. CPC H03K 5/01; H03K 2005/00026

(57) ABSTRACT

A circuit for generating a time delay, including a capacitive element for integrating a first current supplied by a first current source, in which the first current source includes a switched-capacitor circuit.

This application claims priority to French patent application number 18/72691, filed on Dec. 11, 2018, the content of which is incorporated herein by reference it its entirety.

### TECHNICAL FIELD

The present disclosure relates generally to electronic circuits, and more specifically, the programmable circuits for asynchronous delay generation. The present disclosure more specifically relates to circuits based on ramp generators.

### BACKGROUND ART

In many applications, it is desirable to have time delay devices for electronic signals. These may for example be phase comparators, synchronization functions, clock signal generators, transmission circuits, etc. Most often, it is also desirable to be able to program the delay, that is to say, to adjust the value thereof. Furthermore, it is also generally desirable to be able to guarantee the relationship between a setpoint supplied by applying a value of the delay obtained on the signal processed by the time delay device.

The functions for generating a programmable delay generally supply a pulse after a certain amount of time following a triggering event. This time defines the value of the delay. The programming of the delay (setpoint) can assume various analog or digital forms.

The functions or circuits with programmable delay can be broken down into three major categories.

A first category relates to solutions based on digital counters incremented at the rhythm of an oscillator. The triggering event is generally an initialization of the counter.

The delay impulse is triggered when the counter reaches a given count representing the setpoint.

A second category relates to solutions based on time delay elements (most often logic inverters) mounted in a delay locked loop (DLL).

A third category relates to solutions based on a voltage ramp generator from a capacity charge. In these solutions, a voltage ramp is obtained by charging a capacitance under constant current and the delay impulse is generated when the voltage of the ramp reaches a threshold representing the setpoint.

The present disclosure more specifically relates to this third category of time-delay devices.

Document US-A-2012/212265 describes a circuit for generating a delay based on a current source with switched capacitances. One drawback of the solution proposed by this document is that the generated delay is sensitive to the temperature variations, supply voltage and variation speed of the signal to be delayed.

Document US-A-2018/0323696 describes a circuit and a control method of a power converter using a time-delay circuit based on a ramp generator.

Document US-A-2009/0268778 describes a temperature detector and the method for using the same.

Document US-A-2010/0026542 describes a circuit for adaptive bias current generation for switched-capacitor circuits.

Document FR-A-2,975,246 describes a device for generating a sawtooth signal.

### SUMMARY OF INVENTION

There is a need to improve electronic time-delay devices in terms of operating range (range of possible values of the time delay).

There is also a need to improve electronic time-delay devices in terms of resolution (gap between two consecutive values of the time delay).

There is also a need to improve electronic time-delay devices in terms of reliability in case of drifts of the components in particular under the effect of the temperature.

There is also a need to improve electronic time-delay devices in terms of stability with respect to variations in the supply voltage.

An embodiment addresses all or some of the drawbacks of the usual time delay circuits.

An embodiment provides a circuit for generating a time delay, including a capacitive element for integrating a first current supplied by a first current source, in which the first current source includes a switched-capacitor circuit.

According to an embodiment, the circuit further includes a comparator of a first charge voltage of said first capacitive element relative to a second voltage.

According to an embodiment, the second voltage is generated by a first impedance supplied by a second current source supplying a second current proportional to a third current, the third current being generated by a third current source including a second impedance of the same nature as the first impedance.

According to an embodiment, the second current source is a digital-analog converter.

According to an embodiment, a digital value applied to the converter programs the delay.

According to an embodiment, the second voltage is referenced to a first potential greater than a potential to which the first voltage is referenced.

According to an embodiment, the first current source includes at least one first

MOS transistor in series with said switched-capacitor circuit, and an amplifier mounted as a control follower with said first transistor from a first reference voltage.

According to an embodiment, the third current source includes at least one second MOS transistor in series with said second impedance, and an amplifier mounted as a control follower with said second transistor from a second reference voltage.

According to an embodiment, the first reference voltage and the second reference voltage have a same temperature coefficient sign.

According to an embodiment, the first reference voltage and the second reference voltage are equal.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 is a very schematic illustration of an example time-delay device with ramp 1 of the type to which the embodiments that will be described apply;

FIG. 2A, FIG. 2B and FIG. 2c, illustrate the operation of a time delay device with ramp of the type described in connection with FIG. 1;

FIG. 3 shows, very schematically and functionally, an embodiment of a time-delay circuit;

FIG. 4 is a schematic illustration, in block diagram form, of an embodiment of a digitally programmable time-delay circuit;

FIG. 5 schematically shows an embodiment of a digital-analog converter and a current source;

FIG. 6A and FIG. 6B, illustrate the startup of a voltage ramp of the time-delay circuit;

FIG. 7 shows, very schematically and in block diagram form, another embodiment of a time-delay circuit;

FIG. 8 is a partial illustration of an exemplary inner structure of an embodiment of a digital-analog converter;

FIG. 9 schematically shows an embodiment of a current source;

FIG. 10 schematically shows another embodiment of a current source;

FIG. 11 shows, schematically and functionally, another embodiment of a current source;

FIG. 12 shows, schematically and functionally, still another embodiment of a current source;

FIG. 13 shows, very schematically, a block diagram of a time-delay circuit with ramp;

FIG. 14 schematically shows an embodiment of a time-delay circuit as diagrammed in FIG. 13; and

FIG. 15 illustrates, by timing diagrams, an example of control signals of the time-delay circuits of FIGS. 13 and 14.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the intended use of the generated delays has not been described in detail, the embodiments being compatible with the typical intended uses of delayed signals that depend on the application, the described embodiments in particular being compatible with the usual applications of time-delay devices. Furthermore, the generation of the triggering signals or events of the delays generated by the time-delay circuits of the described embodiments have not been described in detail, the described embodiments being compatible with the usual techniques for generating triggering signals, which depend on the application.

Unless indicated otherwise, when reference is made to two elements connected together, this signifies a direct connection without any intermediate element other than conductors, and when reference is made to two elements coupled together, this signifies that these two elements can be directly connected or they can be coupled via one or more other elements.

In the description that follows, the expressions “approximately”, “around” and “in the order of” signify within 10%, and preferably within 5%.

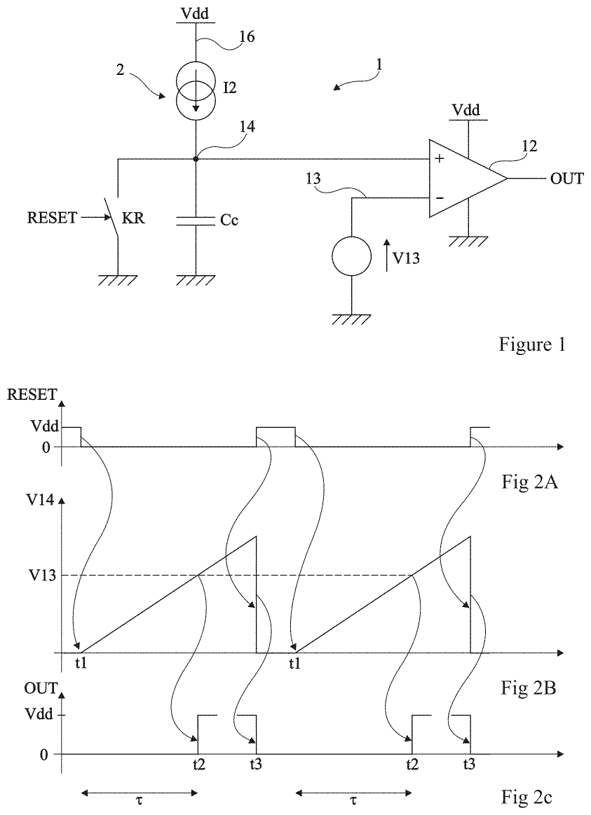

FIG. 1 is a very schematic illustration of an example time-delay device with ramp of the type to which the embodiments that will be described apply.

The circuit includes a comparator 12, an input 13 of which (for example, inverter (−)) receives a reference or setpoint voltage V13 and the other input 14 of which (for example non-inverter (+)) is coupled, preferably connected, to a first electrode of a capacitor Cc, the other electrode of which is coupled, preferably connected, to the ground. The capacitor Cc is configured to be charged by a constant current I2 source 2 supplied by a direct voltage Vdd. The current source 2 couples a terminal 16 for applying the voltage Vdd to the node 14. Furthermore, the node 14 is coupled to the ground by a reset switch KR (signal RESET). The switch KR is in parallel with the capacitor Cc and makes it possible to discharge it each time the switch KR is closed. In other words, an opening of the switch KR constitutes the trigger for the time delay or the initialization of the delay. After each time the switch KR is opened, the potential of the node 14 increases under the effect of the charge of the capacitor Cc by the current I2 supplied by the source 2. Once the potential reaches the threshold corresponding to the voltage V13, the output OUT of the comparator switches.

FIGS. 2A, 2B and 2C are timing diagrams illustrating the operation of a time delay device with ramp of the type described in connection with FIG. 1.

FIG. 2A illustrates an example of the appearance of the signal RESET. FIG. 2B illustrates a corresponding exemplary evolution of the voltage V14 across the terminals of the capacitor Cc. FIG. 2C illustrates the corresponding appearance of the signal OUT representative of the generated delay. The signals RESET and OUT are all-or-nothing signals (0 or 1), while the signal V14 is a voltage ramp.

At each moment t1 where the switch K is open (FIG. 2A), a charge cycle of the capacitor Cc through the current source 2 begins. The voltage V14 (FIG. 2B) begins to grow and, when (moment t2) this voltage V14 reaches the threshold V13, the output OUT (FIG. 2C) of the comparator 12 switches (in this example, toward the high state). The voltage V14 continues to grow after the moment t2, if applicable until saturation, while the discharge of the capacitor Cc is not caused by the closing of the switch KR. From the moment (t3) where the signal RESET returns (arbitrarily) to the high state to close the switch KR, the capacitor Cc is discharged, and it is possible to restart a new cycle.

The high and low levels of the signal OUT are connected to the supply voltage of the comparator 12 and arbitrarily denoted as being Vdd and zero (the ground), in particular neglecting the voltage drops in the transistors in the on state of the comparator 12. Likewise, a signal RESET is arbitrarily assumed for which the high and low states are respectively Vdd and the ground.

The time delay τ (deviation between the moments t1 and t2) can be programmed by controlling the slope of the ramp, that is to say, the charge current or the capacitance of the capacitor Cc, the reference voltage V13 of the comparator 12, or the initial charge of the capacitor Cc.

An analog ramp generation solution as illustrated by FIG. 1 is often preferred to the purely digital solutions of the other two categories (with counter or with logic time delay elements) for its linearity. Indeed, as long as the charge of the capacitor Cc is indeed done under constant current, the analog ramp presented at the non-inverter input 13 of the comparator 12 is indeed linear.

However, such a time delay device is often sensitive to the operating temperature. In particular, heating will affect the value of the capacitor Cc and, in a typical time delay device, cause an offset of the value of the time delay τ under the effect of the temperature. Furthermore, the charge current is in turn sensitive to the temperature.

Such a time delay device is further sensitive to the supply voltage variations of the circuit.

According to an aspect of the present description, an effort is made to improve the temperature and voltage stability of the generated time delay.

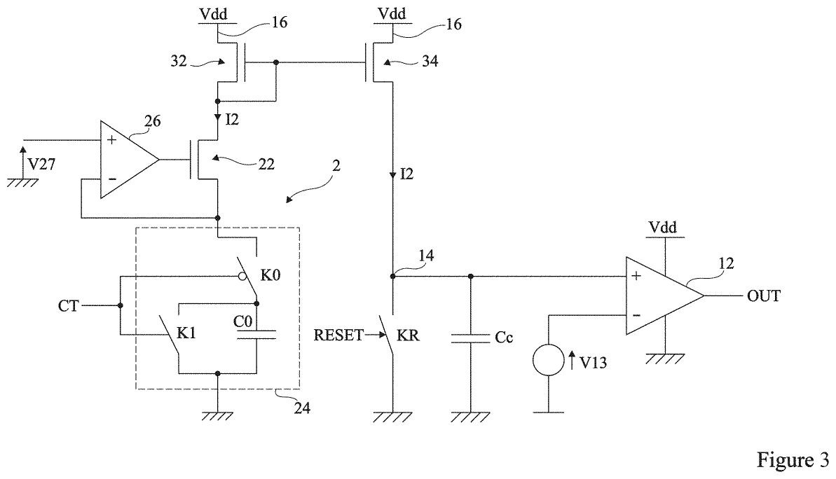

FIG. 3 shows, very schematically and functionally, an embodiment of a time-delay circuit according to this aspect.

According to an embodiment, it is provided to generate the current I2 by a switched-capacitor circuit. Thus, the charge serving to generate the constant current I2 is of the same nature as the capacitance Cc generating the ramp, and their respective contributions, in terms of variation as a function of the temperature and the supply voltage of the circuit, offset one another.

The current source 2 is, in the example of FIG. 3, based on a MOS transistor 22 in series with a switched-capacitor circuit 24. The transistor 22 is controlled by a follower assembly including an operational amplifier 26, a non-inverter input of which (+) receives a reference constant voltage V27 and an inverter input of which (−) is connected between the transistor 22 and the circuit 24. For example, the drain of the transistor 22 is coupled to the terminal 16 applying the supply voltage Vdd and its source is coupled, preferably connected, to a first terminal of the circuit 24 whose other terminal is coupled, preferably connected, to the ground. The circuit 24 therefore sees the voltage V27 on its transistor 22 side terminal.

The circuit 24 for example includes a capacitive element C0 in series with a switch K0 and in parallel with a switch K1. The switches K0 and K1 are controlled alternatingly (in opposition). In FIG. 3, a control is illustrated of the switches K0 and K1 by a same periodic signal CT with frequency f24, and an inversion of the control of the switch K0. Typically, depending on the switching frequency of the switches KO and K1, the circuit 24 is equivalent to a resistive charge.

A current mirror assembly serves to copy the current circulating in the branch of the transistor 22 on the node 14 to which the capacitive element Cc is connected. Such a current mirror assembly is typical in itself. A transistor 32 (for example MOS) couples, preferably connects, the transistor 22 (its drain) to the terminal 16 applying the voltage Vdd. The gate and the drain of the transistor 32 are interconnected. A transistor 34, of the same type as the transistor 32, is mounted in mirror on the transistor 32 with its source coupled, preferably connected, to the terminal 16. The gate of the transistor 34 is coupled, preferably connected, to the gate of the transistor 32 and its drain is coupled, preferably connected, to the node 14. With transistors 32 and 34 having identical surface ratios, the current circulating in the transistor 34, therefore injected on the node 14, is equal to the current I2 circulating in the transistor 22.

The current I2, supplied by the current source 2, is directly proportional to the product of the value of the capacitive element C0 by the voltage V27 and by the frequency f24 of the signal CT. The current I2 can be written:

I2=A×C0×V27×f24 (equation 1)

where A designates a constant.

Yet the voltage V14 of the node 14 can be written:

$$V 14 = \frac{I 2 \times t}{Cc} \qquad ( equation 2 )$$

where t designates the time (since the beginning of charging of the capacitor Cc).

Thus, the voltage V14 can also be written:

$$V 14 = A \times V 27 \times \frac{C 0}{Cc} \times f 24 \times t \qquad ( equation 3 )$$

As a result, the offsets of the capacitive elements C0 and Cc, during temperature and supply voltage variations, have inverted effects, which makes it possible to improve the temperature and voltage stability thereof.

According to a preferred embodiment, it is provided to further decrease the effects of temperature and voltage variations by acting on the generation of the setpoint voltage V13 (FIG. 1) of the time delay.

In a programmable time delay device with voltage ramp, the programming is generally digital, that is to say, the value of the time delay is determined (programmed) by a digital word whose value conditions the value of the voltage V13.

This digital word is converted into an analog signal (into current) by a digital-analog converter, then applied to a current-voltage conversion resistance in order to generate the voltage V13.

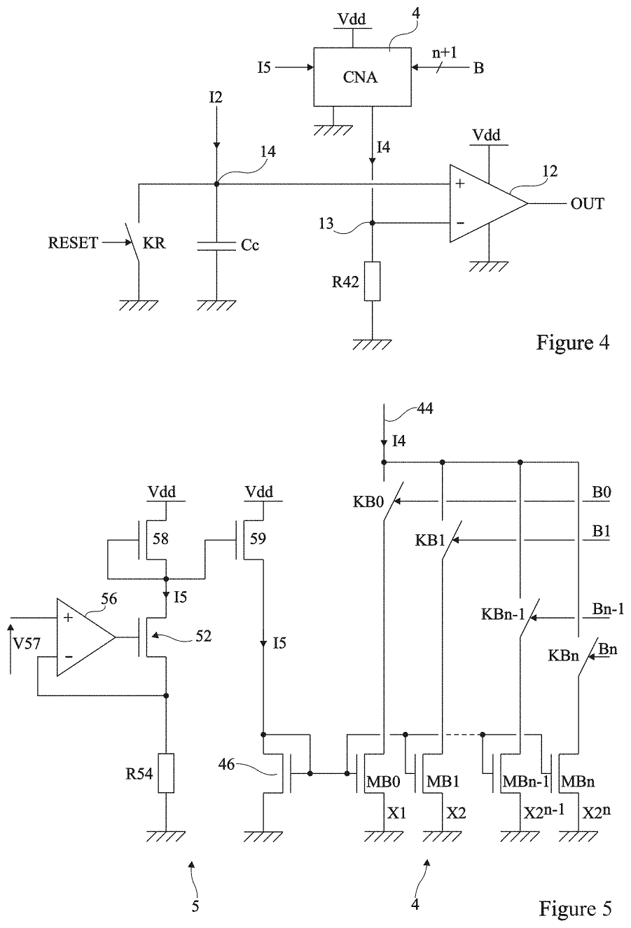

FIG. 4 is a schematic illustration, in block diagram form, of an embodiment of a digitally programmable time-delay circuit.

According to this embodiment, the node 13, corresponding to the inverter input (−) of the comparator 12, is coupled, preferably connected, to a first terminal of a resistance R42 whose other terminal is coupled, preferably connected, to the ground. A digital-analog converter 4 (DAC) converts a binary word B of n+1 (for example between 8 and 16) bits B0, . . . , Bn into a current I4. The output of the converter 4, supplying the current I4, is coupled, preferably connected, to the node 13. The converter 4 is supplied by the voltage Vdd and uses a reference current I5 to generate the current I4.

According to this embodiment, it is provided to generate the current I5 from a resistance so that the effects of temperature and voltage variations are of the same nature on the resistance R42 and on the resistance of the current source 14 and offset one another.

FIG. 5 schematically shows an embodiment of a digital-analog converter 4 and a current I5 source 5.

Like for the generation of the current I2, it is generally preferred to generate the current I4 of the converter relative to a reference to the ground next to make a copy of this current to inject it into the resistance R42. FIG. 5 shows such an embodiment. To simplify, the copy to the resistance R42 is not illustrated, but is in itself typical (see FIG. 3).

The current I4 corresponds to the sum of the currents in n+1 branches in parallel with the converter 4 that are individually controlled by one of the bits Bi (i between 0 and n) of the word B. Each branch includes, between a terminal 44 drawing a current I4 and the ground, a switch KB0, KB1, . . . , Kbn−1, Kbn, and a MOS transistor MB0, MB1, . . . , MBn−1, MBn connected in series. The transistors MBi are mounted in current mirror on a transistor 46 in which the current I5 circulates that is supplied by the constant current source 5. Thus, the drain and the gate of the transistor 46 are interconnected and its source is coupled, preferably connected, to the ground. The gates of the transistors MBi are connected to the gate of the transistor 46. Furthermore, the surface ratios of the transistors MBi double with the rank i. In other words, assuming a transistor MB0 with normalized surface ratio 1 (2⁰), the transistor MB1 has a surface ratio 2 (that is to say, 2¹), a transistor MBi has a surface ratio 2ⁱ, the transistor MBn-1 has a surface ratio 2ⁿ⁻¹ and the transistor MBn has a surface ratio 2ⁿ. Thus, the current I4 can be written:

$$I 4 = I 5 \times {\sum }_{i = 0}^{n} ( Bi \times {2}^{i} ) \qquad ( equation 4 )$$

The current source 5 is, in the example of FIG. 5, based on a MOS transistor 52 in series with a resistance R54. The transistor 52 is controlled by a follower assembly including an operational amplifier 56, a non-inverter input of which (+) receives a reference constant voltage V57 and an inverter input of which (−) is connected between the transistor 52 and the resistance R54. The current I5 passing through the transistor 52 is copied by a current mirror assembly on the transistor 46. For example, a transistor 58 (for example MOS) couples, preferably connects, the transistor 52 (its source) to the terminal 16 applying the voltage Vdd. A transistor 59, of the same type as the transistor 58, is mounted in mirror on the transistor 58 with its source coupled, preferably connected, to the terminal 16, its gate coupled, preferably connected, to the gate of the transistor 58 and its drain coupled, preferably connected, to the drain of the transistor 46. With transistors 58 and 59 having identical surface ratios, the current circulating in the transistor 59, therefore in the transistor 46, is equal to the current I5 circulating in the transistor 52.

To simplify, the current mirror-based assembly (with a composition similar to the assembly based on transistors 58 and 59) has not been shown making it possible to convert the current I4 illustrated in FIG. 5 into the current I4 illustrated in FIG. 4. Such assemblies for converting an extracted current into a supplied current, or vice versa, based on current mirrors with MOS transistors are typical.

An assembly as illustrated by FIGS. 4 and 5 makes it possible to compensate for any temperature variations. Indeed, the current I5 can, on first approximation, be written:

$$I 5 = \frac{V 57}{R 54} \qquad ( equation 5 )$$

and the current I4 can therefore be written:

$$I 4 = \frac{V 57}{R 54} \times {\sum }_{i = 0}^{n} ( Bi \times {2}^{i} ) \qquad ( equation 6 )$$

Yet the voltage V13 defining the setpoint or reference value of the time delay device is equivalent to:

$$V 13 = R 42 \times I 4 \qquad ( equation 7 )$$

As a result, this setpoint voltage V13 can be written:

$$V 13 = \frac{R 42 \times V 57}{R 54} \times {\sum }_{i = 0}^{n} ( Bi \times {2}^{i} ) \qquad ( equation 8 )$$

One can therefore see that with resistances R42 and R54 of the same type having temperature variation coefficients with the same sign and same order of magnitude, preferably the same value, their respective evolutions as a function of the temperature will have inverse effects on the voltage V13 and will therefore be offset. The same is true for any offsets thereof under the effect of variation of the supply voltage.

During operation, when the comparator 12 switches, that is to say, when the voltage ramp reaches the value V13, one has:

$$V 13 = V 1 \; 4. \qquad ( equation 9 )$$

Or (equation 10):

$$\frac{R 42 \times V 57}{R 54} \times {\sum }_{i = 0}^{n} ( Bi \times {2}^{i} ) = A \times V 27 \times \frac{C 0}{Cc} \times f 24 \times τ$$

The equation above can also be written (equation 11):

$$τ = \frac{V 57}{V 27} \times \frac{R 42}{R 54} \times \frac{Cc}{C 0} \times \frac{1}{A \times f 24} \times {\sum }_{i = 0}^{n} ( Bi \times {2}^{i} ) .$$

Advantageously, it is possible to provide voltages V27 and V57 having variation coefficients with the same sign as a function of the temperature and the supply voltage. Thus, the impact of the temperature on the generated time delay is reduced still further.

Equation 11 above indeed shows that in order to obtain a temperature and supply voltage stability (to make the generated time delay insensitive to temperature and supply voltage variations), it suffices for the ratios V57/V27, R42/R45 and Cc/C0 each to be insensitive to such variations. In other words, one ensures that in case of temperature or supply voltage variations of the circuit:
the voltages V57 and V27 vary in the same way (in the same direction and with the same variation amplitude);
the resistances R52 and R54 vary in the same way (in the same direction and with the same variation amplitude); and
the capacitances Cc and C0 vary in the same way (in the same direction and with the same variation amplitude).

In order to obtain a similar variation of the voltages V27 and V57, such that their ratio remains constant in case of temperature or supply voltage variation, it is provided to generate these two voltages from circuits with the same structure, preferably from a same circuit. Furthermore, in the case where the voltages V27 and V57 have different values, it is possible to use a circuit generating a first reference voltage and the other of the reference voltages is obtained by using a voltage divider from the first generated voltage.

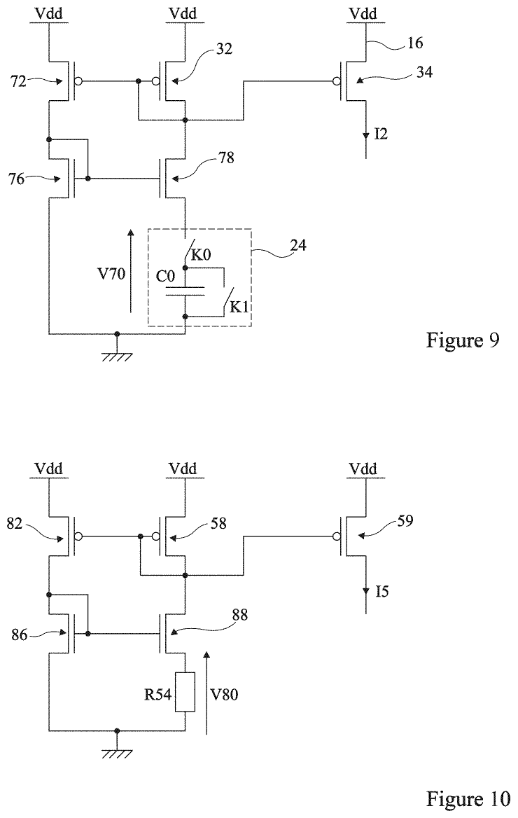

It will be noted that it is not necessary for the voltages V27 and V57 to be equal. It indeed suffices for their ratio to be insensitive to the temperature and supply voltage variations. For example, it is possible to provide for the use, like in the illustrated embodiments, of a current source circuit using a setpoint voltage (V27 or V57) supplied by a circuit generating a reference voltage. According to another example that will be described in detail hereinafter in relation with FIGS. 9 and 10, a current source is used without external voltage reference but a charge of which (resistance or switched capacitance) of the current mirror assembly is, by construction, biased by the structure.

According to a specific embodiment, the voltages V27 and V57 are identical (equal) so that their respective values have the same contribution. Thus, the time delay τ can be expressed:

$$τ = \frac{R 42}{R 54} \times \frac{Cc}{C 0} \times \frac{1}{A \times f 24} \times {\sum }_{i = 0}^{n} ( Bi \times {2}^{i} ) \qquad ( equation 12 )$$

or:

$$τ = cst \times {\sum }_{i = 0}^{n} ( Bi \times {2}^{i} ) \qquad ( equation 13 )$$

where cst represents a constant related to the circuit, and which is temperature-stable.

According to an embodiment variant, the resistive elements R42 and R54 are made in the form of switched capacitances. In order to respect the compensation of the temperature and voltage variation on the voltage V13, both elements R42 and R54 will then be made in the form of switched capacitors, and not only one of them.

More generally, the components (impedances) involved in generating the current 15 and the voltage V13 are of the same nature, preferably passive.

In order to guarantee the stability of the ratios V57/V27 and R42/R54, one ensures that the voltage governed by the terminals of the circuit 24 with switched capacitors at the voltage V27 and the reference voltage V13 of the comparator 12 have similar variations in case of temperature or supply voltage variations. Thus, any variations, under the effect of the temperature or the supply voltage, of the voltages V13 and V27 compared by the comparator 12 are similar.

Moreover, in order to still further improve the stability, the comparator 12 is, as shown in the figure, made in the form of an operational amplifier mounted as a comparator (or differential amplifier) with two inputs (one receiving the reference voltage V13, the other receiving the voltage V14). An advantage is then that the comparison offset is then less sensitive to temperature and voltage variations than a comparison done from inverter assemblies would be. Furthermore, different techniques exist for performing such a comparison that make it possible to make the offset of the comparator practically insensitive to the temperature and voltage variations.

According to a preferred embodiment, it is further preferred to define the programming range of the time delay device in a linear portion of the ramp. Indeed, the inventors have observed that in the vicinity of the moment t1 (FIGS. 2A to 2C), the slope of the voltage V13 is not truly linear.

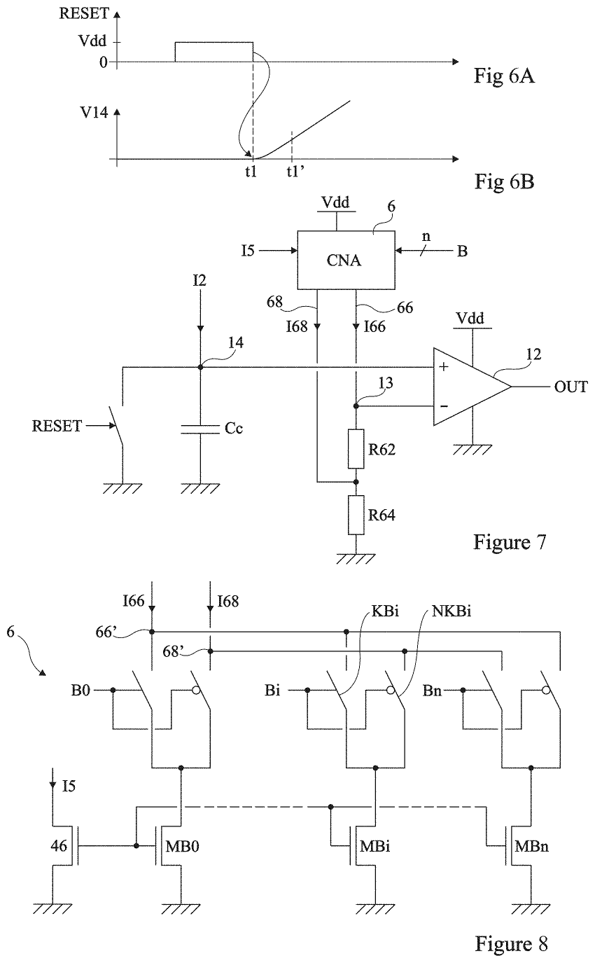

FIGS. 6A and 6B illustrate, by timing diagrams, the startup of a voltage ramp of the time-delay circuit.

These figures are partial and respectively show an example appearance of the signal RESET and the appearance of the voltage V14 under the effect of the charge of the capacitor Cc.

One can see that at the beginning of each charge cycle, the slope of the voltage ramp V14 is not linear, but only becomes so after a time interval that depends on the composition of the circuit and the capacitor Cc. Thus, the slope only becomes linear after a moment t1′.

FIG. 7 shows, very schematically and in block diagram form, an embodiment of a time-delay circuit, avoiding this nonlinear zone.

According to this embodiment, the reference of the voltage V13 is offset such that, irrespective of the value of the word B, the value of the delay is in the linear variation range of the voltage ramp.

The reference input (inverter input (−)) of the comparator 12 is coupled, preferably connected, to the ground by an association in series of two resistances R62 and R64. A digital-analog converter 6 (DAC) includes two current outputs 66 and 68 respectively coupled, preferably connected, to the node 13 and the midpoint of the association in series of the resistances R62 and R64. Additionally, the sum of the currents 166 and 168, supplied by the two outputs 66 and 68, is equal to the reference current I4 (FIG. 4) whose value is independent of the programming word B. Indeed, the composition of the converter causes each branch to contribute, as a function of the state of the bit Bi, either the current I66, or to the current I68.

FIG. 8 is a partial illustration of an exemplary inner structure of an embodiment of a digital-analog converter 6.

The structure is similar to that shown in FIG. 5, with the exception that each branch i includes two switches KBi and NKBi having a common terminal coupled, preferably connected, to the source of the transistor MBi, and the other terminal respectively coupled, preferably connected, to a terminal 66′ or 68′, respectively drawing the current I66 or 168. Like for FIG. 5, the figure has been simplified by not showing the current mirrors making it possible in fact to copy the currents 166 and 168 on the outputs 66 and 68 (FIG. 7). The switches KBi and NKBi of equal rank are controlled by the same bit Bi but in an inverted manner, that is to say, when the bit Bi is in state 1, the switch KBi is closed and the switch NKBi is open, and vice versa.

With such an embodiment, the current I66 can be written:

$$I 66 = I 5 \times {\sum }_{i = 0}^{n} ( Bi \times {2}^{i} ) \qquad ( equation 14 )$$

and the current I68 can be written:

$$I 68 = I 5 \times ( 1 - {\sum }_{i = 0}^{n} ( Bi \times {2}^{i} ) ) \qquad ( equation 15 )$$

Yet the voltage V13 can be written:

V13=V62+V64 (equation 16)

where V62 and V64 represent the voltage drops in the respective resistances

R62 and R64.

The voltages V62 and V64 can be written:

V62=I66×R62=R62×I5×Σᵢ₌₀ⁿ(Bi×2ⁱ) (equation 17)

and

V64=(I66+I68)×R64=R64×I5 (equation 18)

The voltage V13 can therefore be written:

V13=I5×(R64+R62×Σᵢ₌₀ⁿ(Bi×2ⁱ)) (equation 19)

By carrying the value (V57/R54) of the current I5 into the expression above, one obtains:

$$V 13 = \frac{V 57}{R 54} \times ( R 62 \times {\sum }_{i = 0}^{n} ( Bi \times {2}^{i} ) + R 64 ) \qquad ( equation 20 )$$

or

$$V 13 = \frac{V 57}{R 54} \times R 64 + \frac{V 57}{R 54} \times R 62 \times {\sum }_{i = 0}^{n} ( Bi \times {2}^{i} ) \qquad ( equation 21 )$$

The first term

$$\frac{V 57}{R 54} \times R 64 \qquad ( equation 22 )$$

of the equation above defines the time interval t1′-t1 (FIG. 6B) that corresponds to a minimum time delay for which it is considered that the behavior of the time delay device is not linear.

FIG. 9 schematically shows an embodiment of a current source not using an external voltage reference.

The embodiment of FIG. 9 shows an exemplary circuit for generating the current I2.

Relative to the embodiment of FIG. 3, one sees the transistor 34 supplying the current I2 and mounted in current mirror on a transistor 32 of a (first) branch including, inter alia, the switched-capacitor C0 circuit 24. In the embodiment of FIG. 9, the transistor 32 is also mirror-mounted with a transistor 72 of a second branch including, in series between the terminal 16 and the ground, the transistor 72 and a transistor 76. The transistor 76 is also mirror-mounted on a transistor 78 inserted in series between the transistor 32 and the circuit 24 in the first branch. In a known manner, the geometries (W/L) of the transistors 78 and 76 are different (W/L of the transistor 78 greater than the W/L of the transistor 76) so as to unbalance the gate-source voltages of the transistors 76 and 78 and to guarantee that a current circulates in the circuit 24 and thus to allow, by construction, the generation of the current I2. It is possible to consider that the voltage across the terminals of the switched-capacitor circuit 24 is, by construction of the looped current double mirror, governed by a reference voltage V70.

FIG. 10 schematically shows another embodiment of a current source.

The embodiment of FIG. 10 shows an exemplary circuit for generating the current I5.

Relative to the embodiment of FIG. 5, one sees the transistor 59 supplying the current I5 and mounted in current mirror on a transistor 58 of a (first) branch including, inter alia, the resistance R54. In the embodiment of FIG. 10, similarly to the embodiment of FIG. 9, the transistor 58 is also mirror-mounted with a transistor 82 of a second branch including, in series between the terminal 16 and the ground, the transistor 82 and a transistor 86. The transistor 86 is also mirror-mounted on a transistor 88 inserted in series between the transistor 58 and the resistance R54 in the first branch. Likewise, the geometries of the transistors 88 and 86 are different so as to unbalance the gate-source voltages of the transistors 86 and 88 and to guarantee that a current circulates in the resistance R54 and thus to allow, by construction, the generation of the current I5. It is possible to consider that the voltage across the terminals of the resistance R54 is, by construction of the looped current double mirror, governed by a reference voltage V80.

By using differential assemblies as shown in FIGS. 9 and 10 to generate the currents I2 and I5, equation 11, described above in reference to FIGS. 3 and 5, can be written (equation 23):

$$τ = \frac{V 80}{V 70} \times \frac{R 42}{R 54} \times \frac{Cc}{C 0} \times \frac{1}{A \times f 24} \times {\sum }_{i = 0}^{n} ( Bi \times {2}^{i} ) .$$

One will endeavor to use, to generate reference voltages influencing the value of the time delay, a single circuit or circuits with identical structures. In other words, the reference voltages are generated either in the form of (external) voltages V27 and V57 coming from a same circuit, or in the form of (internal) voltages V72 and V80 by circuits of equal structure (by design of the current sources).

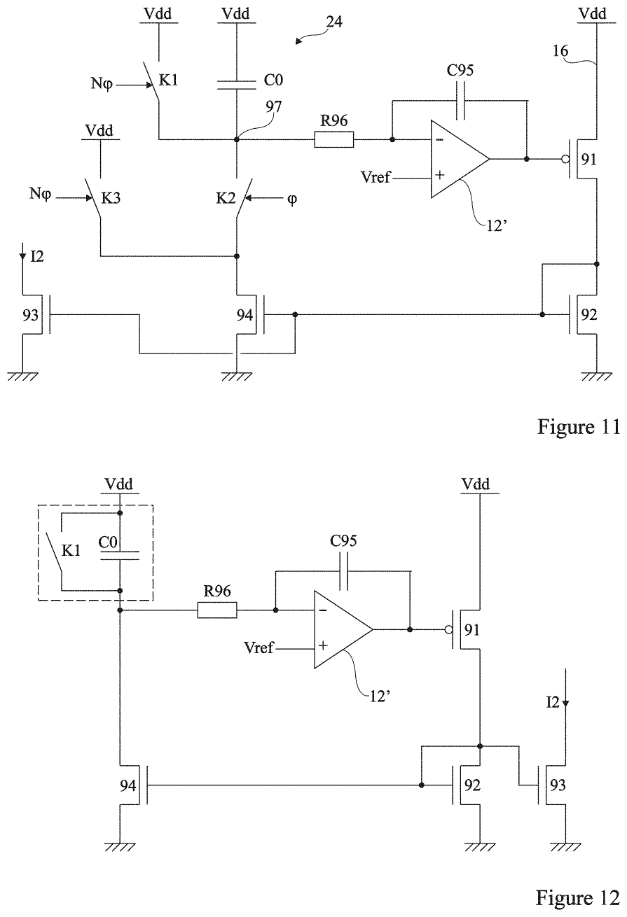

FIG. 11 shows, schematically and functionally, another embodiment of a current source.

The embodiment of FIG. 11 shows an exemplary circuit for generating the current I2.

This embodiment reiterates the principle of the use of an operational amplifier like in FIG. 4 or 7, this amplifier 12′ here further being mounted as an integrator to perform a feedback loop internal filtering function of the voltage across the terminals of the switched-capacitor resistance at a reference voltage Vref. Furthermore, FIG. 11 illustrates the case where the capacitor C0 and the associated reset switch K1 are placed on the terminal side 16 supplying the voltage Vdd.

In the example of FIG. 11, the output of the amplifier 12′ is coupled, preferably connected, to the gate of a PMOS transistor 91 associated in series with an NMOS transistor 92 between the terminal 16 and the ground. The transistor 92 is mounted as a mirror on an NMOS transistor 93 drawing the current I2. The output of the amplifier 12′ is looped on its inverter input by a capacitor C95, this inverter input being coupled, by a resistance R96, to the node 97 between the switch K1 in parallel with the switched capacitor C0 and a switch K2, in turn coupled to the ground by an NMOS transistor 94. The non-inverter input of the amplifier 12′ receives a reference voltage (external such as the voltage V27). The transistor 94 is mounted as a mirror on the transistors 92 and 93. Furthermore, the midpoint between the switches K2 and 94 is coupled to the terminal 16 by a switch K3 coupling, in the closed position, the transistor 94 to the voltage Vdd. The switch K2 is commanded by a signal φ while the switches K1 and K3 are commanded by the inverse N φ of the control signal of the switch K3. The integrator assembly makes it possible to attenuate the variations at the output of the amplifier 12′.

FIG. 12 shows, schematically and functionally, still another embodiment of a current source.

The embodiment of FIG. 11 shows an exemplary circuit for generating the current I2.

The embodiment of FIG. 12 shows a simplified diagram relative to the embodiment of FIG. 11. One can see the same elements with the exception of the switches K2 and K3, the transistor 94 being directly connected to the node 97.

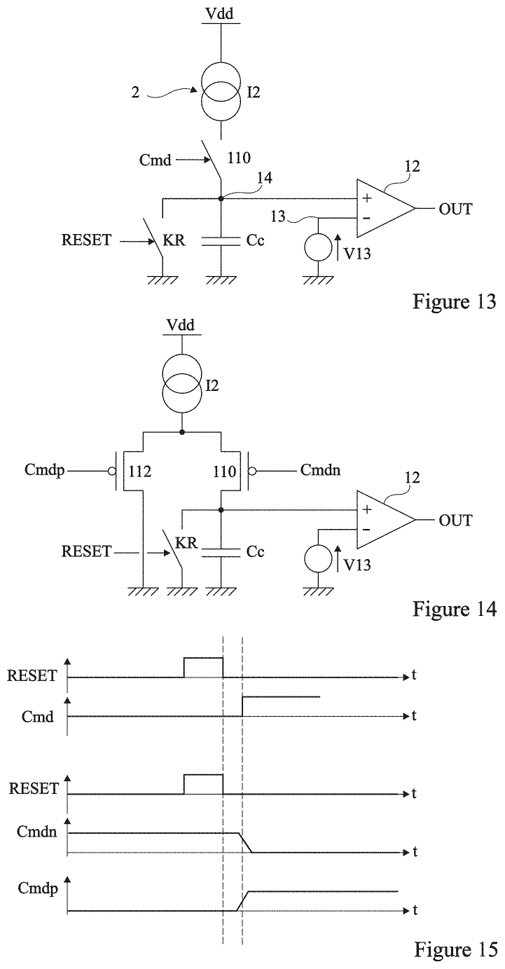

FIG. 13 shows, very schematically, a block diagram of a time-delay circuit with ramp. This diagram makes it possible to show a possible reset method for the integration capacitor Cc.

The diagram of FIG. 13 reiterates all of the elements of the circuit of FIG. 1 and adds a switch 110 between the current source 2 (I2) and the node 14 (terminal of the capacitor Cc and non-inverter input of the amplifier 12), here mounted as comparator).

The switch 110 is controlled by a signal Cmd, and its primary role is to prevent a current I2 from circulating through the reset transistor KR when the latter is made conductive to reset the capacitor Cc. Indeed, the circulation of a current I2 through the reset transistor KR during the discharge phase induces a “residual” voltage across the terminals of the transistor, therefore the capacitor, at the end of resetting. This residual voltage can vary as a function of the temperature, the supply voltage, and furthermore as a function of the value of the current I2, which can be detrimental for a use of the time-delay circuit in which the current I2 is made variable to change the charge slope of the capacitor Cc.

FIG. 14 schematically shows an embodiment of a time-delay circuit as diagrammed in FIG. 13.

The embodiment of FIG. 14 is an improved diagram of the time-delay circuit of FIG. 13.

Relative to the circuit of FIG. 13, a PMOS transistor 112 couples the current source 2 directly to the ground, the switch 110 here being symbolized by another PMOS transistor. The transistors 110 and 112 are controlled by inverted signals Cmdp and

Cmdn. The use of a “complementary” switch 112, deriving the current from the ground, makes it possible to ensure that the current source 12 is fully functional at the moment when it is coupled to the capacitance Cc, and allows lower values of the voltages Cmdp and Cmdn because it is the difference in potential that matters for the activation of one branch or another and not their absolute values. In practice, it suffices to have several hundred millivolts in difference and not a full voltage excursion (0-1 V), which makes it possible to switch these control voltages more quickly for better precision of the time delay, in particular its “starting” edge.

FIG. 15 illustrates, by timing diagrams, an example of control signals of the time-delay circuits of FIGS. 13 and 14.

The first two timing diagrams illustrate the operation of the diagram of FIG. 13, while the last three timing diagrams illustrate the operation of the diagram of FIG. 14.

As shown by these timing diagrams, the signals Cmd (second timing diagram) and the signals Cmdn and Cmdp (fourth and fifth timing diagrams) are delayed relative to the end of the reset timeslot of the capacitance (signal RESET in the high state) in order to ensure a complete reset of the capacitance Cc, not disrupted by the current I2. In the case where the startup of the period is given by the falling edge of the reset signal, an effort will be made to minimize this offset between the falling edge of the signal RESET and the following edges of the control signals Cmd (or Cmdn and Cmdp). In a variant, the beginning of the period may correspond to the activation edge of the control signals allowing the current I2 to circulate and to charge the capacitance Cc.

An advantage of the embodiments described according to the first aspect hereinabove is that one obtains a digitally programmable time delay device that is stable in terms of temperature and voltage and the programming of which is done in a linear portion of the generated voltage ramp.

Another advantage is that the combination of the analog integration of the reference current I2 in order to obtain the voltage ramp, and the digital programming of the desired time delay, provides not only a fine resolution (which depends on the number of bits of the digital-analog converter), but also a wide operating range.

The determination of the different values to be given to the components of the time delay device depends on the application. These values can be set by applying the described formulas, then refined empirically or through tests.

Various embodiments and variants have been described. Certain features of these embodiments can be combined and other variants will readily occur to those skilled in the art. In particular, although reference has specifically been made to a programmable time delay generator, the described embodiments can be transposed to a fixed-value time delay generator (frozen upon manufacturing the circuit), then having the same advantages in terms of temperature and supply voltage stability. It in fact suffices to provide, as voltage V13, a nonadjustable fixed reference voltage. Furthermore, the determination of the different values and the sizing of the components depends on the application and is within the capabilities of one skilled in the art from the functional description given above.

What is claimed is:

1. A circuit for generating a time delay, including:
a capacitive element for integrating a first current supplied by a first current source including a switched-capacitor circuit;
a device for governing of the voltage across the terminals of the switched-capacitor circuit by a first reference voltage;
a first discharge switch of the capacitive element;
an operational amplifier, mounted as a comparator, a first input of which receives a charge voltage of said capacitive element, a second input of which receives a second reference voltage, and an output of which receives a signal representative of the generated time delay,
such that the first reference voltage and the charge voltage have similar variations following temperature or supply voltage variations.

2. The circuit according to claim 1, wherein the second reference voltage is generated by a first impedance supplied by a second current source supplying a second current proportional to a third current, the third current being generated by a third current source including a second impedance of the same nature as the first impedance.

3. The circuit according to claim 2, wherein the second current source comprises a digital-analog converter making it possible to choose among several proportionality coefficients between the second current and third coefficients.

4. The circuit according to claim 3, wherein a digital value applied to the converter programs the delay.

5. The circuit according to claim 1, wherein the reference voltages are generated by one or several circuits with identical structures.

6. The circuit according to claim 1, wherein the first current source includes at least one first MOS transistor in series with said switched-capacitor circuit, and an amplifier mounted as a control follower with said first transistor from a first reference voltage.

7. The circuit according to claim 2, wherein the third current source includes at least one second MOS transistor in series with said second impedance, and an amplifier mounted as a control follower with said second transistor from a second reference voltage.

8. The circuit according to claim 6, wherein the first reference voltage and the third reference voltage have a same temperature coefficient sign.

9. The circuit according to claim 6, wherein the first reference voltage and the third reference voltage are equal.

10. The circuit according to claim 1, wherein the first current source includes a differential assembly, one branch of which includes the switched-capacitor circuit, mirror transistors of each of the branches having different surface ratios from one another.

11. The circuit according to claim 10, wherein the third current source includes a differential assembly, one branch of which includes the second impedance, mirror transistors of each of the branches having different surface ratios from one another.

12. The circuit according to claim 1, wherein the switched-capacitor circuit is controlled by a periodic signal.

13. The circuit according to claim 1, wherein the operational amplifier is mounted as an integrator of the voltage across the terminals of the switched-capacitor circuit.

14. The circuit according to claim 1, further including a second switch between the first current source and a first terminal of the capacitive element.

15. The circuit according to claim 14, further including a third switch between the first current source and a ground of the circuit.
